(19) United States
(12) Patent Application Publication
(10) Pub. No.: US 2009/0166690 A1
(43) Pub. Date: Jul. 2, 2009

(54) Image Sensor and Method of Manufacturing the Same

(76) Inventor: Jong Min Kim, Guro-gu (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/258,499

(22) Filed: Oct. 27, 2008

(30) Foreign Application Priority Data
Dec. 26, 2007 (KR) 10-2007-0137055

(51) Int. Cl. H01L 31/112; H01L 21/265

(52) U.S. Cl. 257/292; 438/527; 257/E31.073; 257/E21.334

(57) ABSTRACT

An image sensor and manufacturing method thereof are provided. The image sensor can include a gate, a channel region, a first p-type doped region, a second p-type doped region, an n-type doped region, and a floating diffusion region. The gate can be disposed on a semiconductor substrate, and the channel region can be disposed in the semiconductor substrate under the gate. The first p-type doped region can be disposed at a side of the gate and can be adjacent to the channel region. The second p-type doped region can be disposed under the first p-type doped region and spaced apart from the gate. The n-type doped region can be disposed under the first and second p-type doped regions, and the floating diffusion region can be disposed at another side of the gate.

### CROSS-REFERENCE TO RELATED APPLICATION

The present application claims the benefit under 35 U.S.C. §119 of Korean Patent Application No. 10-2007-0137055, filed Dec. 26, 2007, which is hereby incorporated by reference in its entirety.

### BACKGROUND

An image sensor is a semiconductor device for converting an optical image into an electrical signal. The image sensor can be classified as a charge coupled device (CCD) image sensor or a complementary metal oxide semiconductor (CMOS) image sensor (CIS).

In general, a CIS sequentially detects output with metal oxide semiconductor (MOS) transistors in a switching manner. The number of MOS transistors corresponds to the number of pixels according to a CMOS technology where a control circuit and a signal-processing circuit are used as a peripheral circuit.

The CIS typically includes a photodiode for receiving light and generating photoelectric charges, and the MOS transistors arranged according to unit pixels.

The MOS transistors can include a transfer transistor, a reset transistor, an access transistor, and a select transistor. The transfer transistor transfers photoelectric charges generated in the connected photodiode to a floating diffusion region. The reset transistor sets an electric potential of the floating diffusion region to a desired level and resets the floating diffusion region by discharging photoelectric charges. The access transistor serves as a source follower buffer amplifier, in which a voltage of the floating diffusion region is applied to a gate. The select transistor performs an addressing through a switching operation.

The transfer transistor generally includes a gate, a channel for delivering electric charges, and a drain used as the floating diffusion region (hereinafter, the drain is referred to as the floating diffusion region).

In typical operation of a transfer transistor, when light is incident to the photodiode, photoelectric charges are generated, and the gate of the transfer transistor is turned on. Then, a threshold voltage controlled by the channel is lowered, and the photoelectric charges generated in the photodiode are moved to the floating diffusion region through the channel.

As CISs become increasingly integrated, the size of a unit pixel decreases and the size of a photo response region, i.e., the photodiode also decreases.

A leakage current can often be generated by a high electric field in a junction region of the photodiode.

Thus, the characteristics of a dark leakage current need to be improved by changing the structure of the photodiode of the image sensor such that the electric field of the photodiode can be decreased without affecting charge transfer efficiency.

### BRIEF SUMMARY

Embodiments of the present invention provide an image sensor and a manufacturing method thereof capable of decreasing the electric field of a junction region in a photodiode to inhibit a leakage current and improve the performance of the photodiode.

In one embodiment, an image sensor can comprise: a gate on a semiconductor substrate; a channel region in the semiconductor substrate under the gate; a first p-type doped region at a first side of the gate and adjacent to the channel region; a second p-type doped region under the first p-type doped region and spaced apart from the gate; an n-type doped region in the semiconductor substrate, wherein at least a portion of the n-type doped region is under the second p-type doped region; and a floating diffusion region at a second side of the gate.

In another embodiment, a method of manufacturing an image sensor can comprise: forming a channel region in a semiconductor substrate; forming a gate on the channel region; forming a first p-type doped region at a first side of the gate; forming a second p-type doped region under the first p-type doped region, wherein the second p-type doped region is spaced apart from the gate; forming an n-type doped region in the semiconductor substrate, wherein at least a portion of the n-type doped region is under the second p-type doped region; and forming a floating diffusion region at a second side of the gate.

The details of one or more embodiments are set forth in the accompanying drawings and the description below. Other features will be apparent to one skilled in the art from the detailed description, the drawings, and the claims.

### BRIEF DESCRIPTION OF THE DRAWINGS

FIGS. 1 to 5 are cross-sectional views showing a process of manufacturing an image sensor according to an embodiment of the present invention.

FIG. 6A is a graph showing doping concentration versus doping depth.

FIG. 6B is a graph showing electric field versus doping depth.

### DETAILED DESCRIPTION

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

FIG. 5 is a cross-sectional view showing an image sensor according to an embodiment of the present invention.

The image sensor can include a gate 50, a channel region 40, a first p-type doped region 60, a second p-type doped region 70, an n-type doped region 80, and a floating diffusion region 100. The gate 50 can be disposed on a semiconductor substrate 10, and the channel region 40 can be disposed in the semiconductor substrate 10 under the gate 50. The first p-type doped region 60 can be disposed at one side of the gate 50 and adjacent to and in contact with the channel region 40. The second p-type doped region 70 can be spaced apart from the gate 50 and disposed under the first p-type doped region 60.

The n-type doped region 80 can be disposed under the first p-type doped region 60 and the second p-type doped region 70. The floating diffusion region 100 can be disposed on a side of the gate 50 opposite the first p-type doped region 60.

In an embodiment, the semiconductor substrate 10 can be a heavily doped p-type substrate (p⁺⁺). A lightly doped p-type layer (p-Epi) can be disposed on the semiconductor substrate 10. The p-Epi layer can be formed by performing an epitaxial process.

A photodiode (PD), including the first p-type doped region 60, the second p-type doped region 70, and the n-type doped region 80, can be disposed at one side of the gate 50. The floating diffusion region 100 can be disposed at the other side of the gate 50.

The first p-type doped region 60 can be disposed such that it is in contact with the channel region 40. In an embodiment, the second p-type doped region 70 can be spaced apart form the gate 50 and disposed under the first p-type doped region 60 to have a step-like structure with the first p-type doped region 60. The n-type doped region 80 can be disposed in a deep region in the semiconductor substrate 10 including the first and second p-type doped regions 60 and 70 such that the n-type doped region 80 is disposed under the first and second p-type doped regions 60 and 70. Additionally, the n-type doped region 80 can extend to a region under the channel region 40.

Thus, the photodiode can have a PNP structure. Though a PNP photodiode is described by way of example, embodiments of the present invention are not limited thereto.

In an embodiment, the first p-type doped region 60 can be formed of high concentration p-type impurities (p⁺⁺), and the second p-type doped region 70 can be formed of low concentration p-type impurities (p⁻). For example, the first and second p-type doped regions 60 and 70 can each include BF₂ or boron (B) ions, and the n-type doped region 80 can include arsenic (As) or phosphorus (P) ions.

In an embodiment, the second p-type doped region 70 disposed under the first p-type doped region 60 can have a width that is smaller than that of the first p-type doped region 60. That is, the second p-type doped region 70 can be spaced apart from the gate 50 and can have a step-like structure with the first p-type doped region 60. Also, the second p-type doped region 70 can have a depth that is from about 2 to about 10 times greater than that of the first p-type doped region 60.

Thus, the lightly doped second p-type doped region 70 can be disposed between the n-type doped region 80 and the first p-type doped region 60 to form an upper junction region of the photodiode and reduce an upper junction field.

An image sensor according to embodiments of the present invention can include a p-type doped region of a photodiode in a step-like structure, so that the upper junction field of the photodiode can be reduced while keeping transfer characteristics to the channel of a transfer transistor from the photodiode. Thus, an abnormal leakage current of the photodiode that may occur due to a high electric field can be minimized. This makes it possible to improve dark noise or hot pixel characteristics.

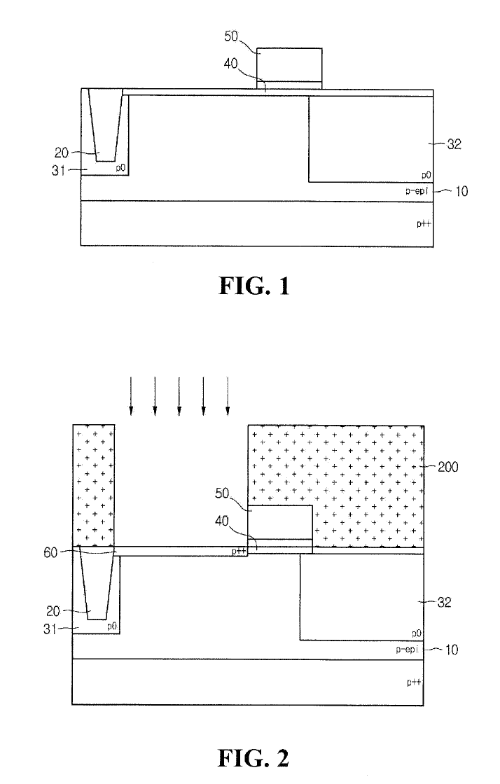

Methods of manufacturing an image sensor according to embodiments of the present invention will now be described with reference to FIGS. 1 to 5.

Referring to FIG. 1, the gate 50 can be formed on the semiconductor substrate 10.

The semiconductor substrate 10 can be a heavily doped p-type substrate (p⁺⁺), and, in an embodiment, an epitaxial process can be performed on the semiconductor substrate 10 to form a lightly doped p-type layer (p-Epi).

A device isolation layer 20 can be formed to define an active region and a field region in a predetermined region of the semiconductor substrate 10. The device isolation layer 20 can be formed through any suitable process known in the art, for example, a shallow trench isolation (STI) process.

The semiconductor substrate 10 can include a first p-type well region 31 and a second p-type well region 32. The first p-type well region 31 can be adjacent to the device isolation layer 20 at one side of the gate 50. The second p-type well region 32 can be formed on the semiconductor substrate 10 at the opposite side of the gate. In an embodiment, a portion of the second p-type well region can be formed under the gate 50.

To provide control of a threshold voltage and to be able to move electric charges, impurity ions can be implanted into the surface of the semiconductor substrate 10 to form the channel region 40.

The gate 50 can be formed on the semiconductor substrate 10 in the active region defined by the device isolation layer 20. The gate 50 can be formed using any suitable process known in the art, such as by depositing and patterning a gate dielectric and a gate conductive layer. For example, the gate conductive layer can be formed in a single layer or a multi-layer structure including poly-silicon, a metal (such as tungsten), and metal silicide.

Referring to FIG. 2, the first p-type doped region 60 can be formed at one side of the gate 50. The first p-type doped region 60 can be formed by implanting p-type dopants at a high concentration (p⁺⁺). For example, the first p-type doped region 60 can be formed by implanting BF₂ or B ions at a high concentration.

In an embodiment, the first p-type doped region 60 can be formed by first forming a photoresist pattern 200 exposing a portion of the semiconductor substrate 10 at one side of the gate 50 and then performing an ion implantation process using the photoresist pattern 200 as an ion implantation mask. When performing the ion implantation process, p-type dopants can be implanted into the semiconductor substrate 10 at a high concentration. During the ion implantation process, a tilt angle of from about 0° to about 15° can be used.

In a particular embodiment, the first p-type doped region 60 can be formed by implanting BF₂ ions at an implantation energy of from about 10 keV to about 40 keV.

Accordingly, the first p-type doped region 60 can be formed in a shallow region of the surface of the semiconductor substrate 10.

Referring to FIG. 3, the second p-type doped region 70 can be formed under the first p-type doped region 60. The second p-type doped region 70 can be formed by implanting p-type dopants at a low concentration (p-). That is, the impurity concentration in the second p-type doped region 70 can be lower than the impurity concentration in the first p-type doped region 60. For example, the second p-type doped region 70 can be formed by implanting BF₂ or B ions at a low concentration. In an embodiment, the second p-type doped region 70 can be formed with a depth of from about 2 to about 10 times greater than that of the first p-type doped region 60.

In an embodiment, the second p-type doped region 70 can be formed through an ion implantation process using the photoresist pattern 200 as an ion implantation mask. When performing the ion implantation process, p-type dopants can be implanted into the semiconductor substrate 10 at a low concentration. During the ion implantation process, a tilt angle of from about 10° to about 45° can be used. At this point, the photoresist pattern 200 can be the photoresist pattern 200 used for the first p-type doped region 60.

In a particular embodiment, the second p-type doped region 70 can be formed by implanting BF₂ ions at an implantation energy of from about 60 keV to about 160 keV and a dopant dose of from about 0.5×10¹² cm⁻² to about 3×10¹² cm⁻².

In an alternative embodiment, the second p-type doped region 70 can be formed by implanting B ions at an implantation energy of from about 15 keV to about 20 keV and a dopant dose of from about 0.5×10¹² cm⁻²to about 3×10¹² cm⁻².

Since the ion implantation process can be performed on the second p-type doped region 70 with a greater energy than that of the first p-type doped region 60, the second p-type doped region 70 can be formed under the first p-type doped region 60. In certain embodiments, a p-type doping profile can have a step-like shape which can help reduce electric field intensity.

Also, since the second p-type doped region 70 can be formed through an ion implantation process with a tilt angle, the second p-type doped region 70 can be spaced apart from an edge of the gate 50. That is, in certain embodiments, since the second p-type doped region 70 can be formed through an ion implantation process with a tilt angle of from about 10° to about 45°, the second p-type doped region 70 can be spaced apart from the gate 50. Accordingly, this makes it possible to improve charge transfer characteristics between the channel region 40 and the n-type doped region 80 to be formed later. For example, in an embodiment, a gap between the second p-type doped region 70 and the gate 50 can be from about 0.05 μm to about 0.25 μm.

Referring to FIG. 4, the n-type doped region 80 can be formed in the semiconductor substrate 10 under the first p-type doped region 60 and the second p-type doped region 70. The n-type doped region 80 can be formed by implanting n-type impurities (n0). For example, the n-type doped region 80 can be formed by implanting As or P ions. The n-type doped region 80 can be formed in a deeper region of the semiconductor substrate 10 than that of the second p-type doped region 70.

In an embodiment, the n-type doped region 80 can be formed through an ion implantation process using the photoresist pattern 200 as an ion implantation mask. During the ion implantation process, n-type dopants can be implanted into the semiconductor substrate 10 at a tilt angle of from about 0° to about 15°. For example, the n-type doped region 80 can be formed by performing an ion implantation process at an implantation energy of about 2 to about 10 times greater than that of the second p-type doped region 70. Accordingly, the n-type doped region 80 can be formed in a deep region of the semiconductor substrate 10. The photoresist pattern 200 can be the photoresist pattern 200 used when forming the first p-type doped region 60 and/or the second p-type doped region 70.

As described above, the PNP photodiode can be formed, including the first p-type doped region 60, the second p-type doped region 70, the n-type doped region 80, and the semiconductor substrate 10. The second p-type doped region 70 can be formed between the first p-type doped region 60 and the n-type doped region 80 to help reduce junction field. Though a PNP photodiode is described by way of example, embodiments of the present invention are not limited thereto.

Additionally, although a method has been described in which the first p-type doped region 60, the second p-type doped region 70, and the n-type doped region 80 are sequentially formed, embodiments of the present invention are not limited thereto. For example, the second p-type doped region 70 and the n-type doped region 80 can be formed before the first p-type doped region 60. In another embodiment, the second p-type doped region 70 can be formed after forming the n-type doped region 80 and the first p-type doped region 60.

Although not shown, in one embodiment, the second p-type doped region 70 can be provided by forming spacers 90 through a subsequent process and then performing an ion implantation process using the spacers 90 as an ion-implantation mask. Thus, the second p-type doped region 70 can be spaced apart form the gate 50 and have a step-like structure with the first p-type doped region 60. Also, an additional mask process for forming the second p-type doped region 70 can be omitted, thereby simplifying the process.

Referring to FIG. 5, spacers 90 can be formed on the sidewalls of the gate 50, and the floating diffusion region 100 can be formed to receive photoelectrons generated in the photodiode on one side of the gate 50. In an embodiment, a photoresist pattern (not shown) exposing a portion of the semiconductor substrate 10 at a side of the gate 50 can be formed, and then the photoresist pattern can be used as an ion implantation mask to form an LDD region. Thereafter, the photoresist pattern can be removed, and the spacers 90 can be formed on the sidewalls of the gate 50. Then, n-type impurities can be implanted at high concentration at the side of the gate 50 to form the floating diffusion region 100.

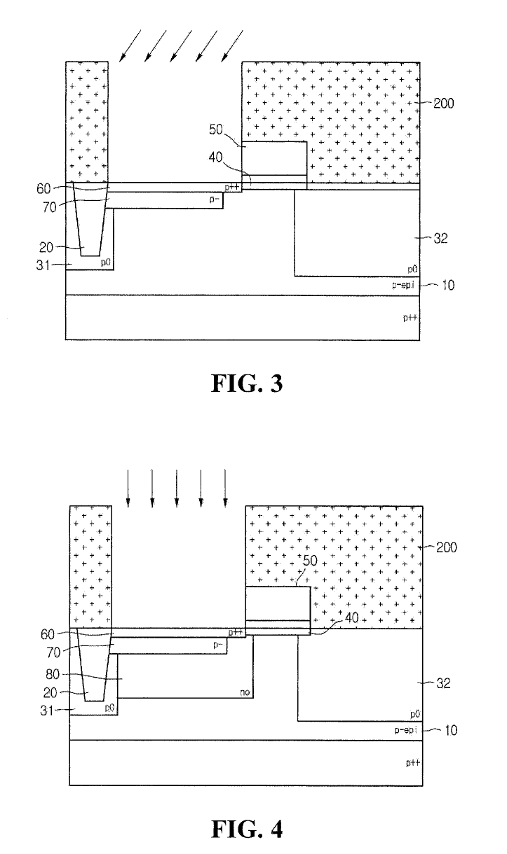

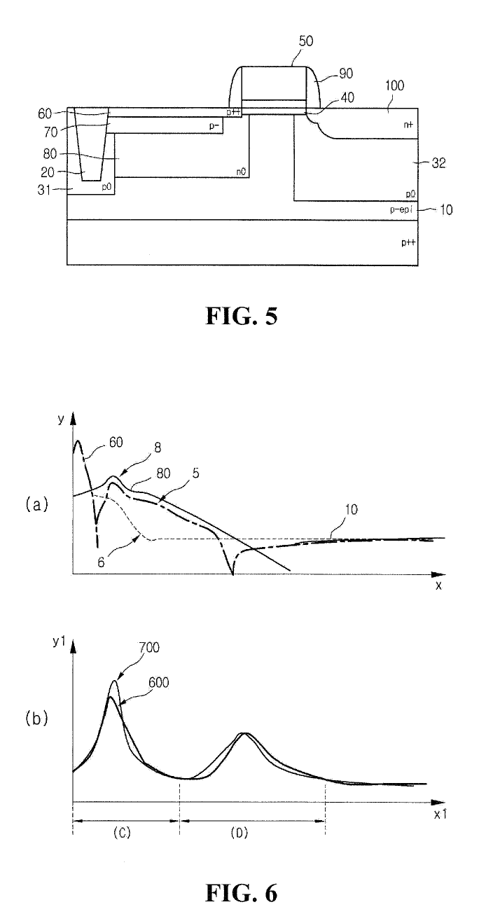

FIG. 6A is a graph showing doping concentration versus doping depth. The x-axis represents the doping depth, and y-axis represents the doping concentration of the impurities. FIG. 6B is a graph showing electric field versus doping depth. The x1-axis represents the doping depth, and the y1-axis represents the electric field intensity of the impurities.

Referring to FIG. 6A, reference numeral 8 denotes a profile of an n-type doped region, reference numeral 6 denotes a profile of a p-type doped region, and reference numeral 5 denotes a net doping profile (where (n-type doping profile)+(p-type doping profile)=(net change)) formed by the n-type and the p-type doped regions according to an embodiment of the present invention. Particularly, the profile of the p-type doped region has a step-like shape with the first p-type doped region 60 and the second p-type doped region 70. Thus, the net doping profile also displays a step-like shape.

Referring to FIG. 6B, reference numerals 600 and 700 denote the electric field characteristics of a photodiode according to embodiments of the present invention and the electric field characteristics of a related art photodiode, respectively. Although not shown, the related art photodiode includes a p-type semiconductor substrate, an n-type doped region, and a high concentration p-type doped region, and an upper junction region (C). The point where the n-type doped region and the high concentration p-type doped region join has high electric field characteristics, and thus exhibits a Gaussian distribution. Since the p-type doping profile has a step-like shape according to the present invention, the upper junction region (C) has a lower electric field characteristic curve than that of the related art. Meanwhile, reference letter (D) of FIG. 6B denotes a lower junction region.

The p-type doping profile shows the step shape, and the electric field is reduced in the upper junction region (C), thereby suppressing the generation of a leakage current due to a high electric field, thereby also suppressing dark noise and hot pixel issues. This makes it possible to improve the quality of an image sensor.

Also, while the first p-type doped region 60 can be maintained as is, the lower second p-type doped region 70 can be formed, thereby improving the transfer efficiency of photoelectrons generated in the photodiode.

Additionally, since, in certain embodiments, the second p-type doped region 70 can be formed with the photoresist pattern 200 used when forming the first p-type doped region 60, the second p-type doped region 70 can be formed without an additional mask process, thereby improving the quality of the image sensor and the efficiency of the manufacturing method of the image sensor.

According to embodiments of the present invention, the low concentration second p-type doped region can be formed between the first p-type doped region and the n-type doped region in the upper junction region of the photodiode, thereby decreasing the electric field of the upper junction. Accordingly, the electric field intensity generated in the upper junction region can be decreased to reduce a leakage current due to the electric field intensity and improve dark noise and hot pixel characteristics.

Any reference in this specification to “one embodiment,” “an embodiment,” “example embodiment,” etc., means that a particular feature, structure, or characteristic described in connection with the embodiment is included in at least one embodiment of the disclosure. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a gate on a semiconductor substrate;
a channel region in the semiconductor substrate under the gate;
a first p-type doped region at a first side of the gate and adjacent to the channel region;
a second p-type doped region under the first p-type doped region and spaced apart from the gate;
an n-type doped region in the semiconductor substrate, wherein at least a portion of the n-type doped region is under the second p-type doped region; and
a floating diffusion region at a second side of the gate.

2. The image sensor according to claim 1, wherein an impurity concentration of the first p-type doped region is higher than an impurity concentration of the second p-type doped region.

3. The image sensor according to claim 1, wherein a width of the first p-type doped region is greater than a width of the second p-type doped region.

4. The image sensor according to claim 3, wherein the first p-type doped region and the second p-type doped region form a step-like shape.

5. The image sensor according to claim 1, wherein a depth of the second p-type doped region is from about 2 to about 10 times greater than a depth of the first p-type doped region.

6. The image sensor according to claim 1, wherein the floating diffusion region is adjacent to the channel region.

7. The image sensor according to claim 1, further comprising:
a first p-type well region at a side of the n-type doped region; and
a second p-type well region in the semiconductor substrate, wherein the floating diffusion region is disposed in the second p-type well.

8. The image sensor according to claim 7, wherein a portion of the second p-type well region is under the gate.

9. The image sensor according to claim 7, wherein the second p-type well region is adjacent to the channel region.

10. A method of manufacturing an image sensor, comprising:
forming a channel region in a semiconductor substrate;
forming a gate on the channel region;
forming a first p-type doped region at a first side of the gate;
forming a second p-type doped region under the first p-type doped region, wherein the second p-type doped region is spaced apart from the gate;
forming an n-type doped region in the semiconductor substrate, wherein at least a portion of the n-type doped region is under the second p-type doped region; and
forming a floating diffusion region at a second side of the gate.

11. The method according to claim 10, wherein forming the first p-type doped region comprises performing a first ion implantation process using an ion implantation mask, and wherein forming the second p-type doped region comprises performing a second ion implantation process using the ion implantation mask.

12. The method according to claim 11, wherein the second ion implantation process is performed at a tilt angle of from about 10° to about 45°.

13. The method according to claim 10, wherein the n-type doped region is formed before the first p-type doped region is formed and before the second p-type doped region is formed.

14. The method according to claim 10, wherein an impurity concentration of the first p-type doped region is higher than an impurity concentration of the second p-type doped region.

15. The method according to claim 10, wherein forming the first p-type doped region comprises performing an ion implantation process at a tilt angle of from about 0° to about 15°.

16. The method according to claim 10, wherein forming the second p-type doped region comprises performing an ion implantation process at a tilt angle of from about 10° to about 45°.

17. The method according to claim 10, wherein forming the first p-type doped region comprises performing a first ion implantation process at a first implantation energy, and wherein forming the second p-type doped region comprises performing a second ion implantation process at a second implantation energy that is from about 2 to about 10 times greater than the first implantation energy.

18. The method according to claim 17, wherein forming the n-type doped region comprises performing a third ion implantation process at a third implantation energy that is from about 2 to about 10 times greater than the second implantation energy.

19. The method according to claim 10, wherein forming the second p-type doped region comprises performing an ion implantation process using a spacer at the first side of the gate as an ion implantation mask.

20. The method according to claim 10, wherein forming the n-type doped region comprises performing an ion implantation process at a tilt angle of from about 0° to about 15°.
